(19) United States
(12) Patent Application Publication
(10) Pub. No.: US 2006/0058973 A1
(43) Pub. Date: Mar. 16, 2006

(54) Built-in-self-test (BIST) circuit with digital output for phase locked loops-jitter testing and method thereof

(75) Inventor: Yu-Chen Chen, Taipei (TW)

Correspondence Address: BIRCH STEWART KOLASCH & BIRCH, PO BOX 747, FALLS CHURCH, VA, 22040-0747, US

(73) Assignee: Ali Corporation

(21) Appl. No.: 11/007,350

(22) Filed: Dec. 9, 2004

(30) Foreign Application Priority Data
Sep. 10, 2004 (TW) 93127590

(51) Int. Cl. G01R 29/26

(52) U.S. Cl. 702/69

(57) ABSTRACT

A built-in-self-testing (BIST) circuit with digital output for phase locked loops-jitter testing and the method thereof are used to solve the problems of difficult processing and test of high frequency signals encountered during test of jitter signal of phase locked loops. The built-in-self-testing (BIST) circuit with digital output for phase locked loops-jitter testing comprises a phase locked loop unit electrically connected with a frequency divide unit. The frequency divide unit is electrically connected with a signal conversion unit. A digital computation unit is electrically connected with the signal conversion unit. A maximum hold circuit is electrically connected with the digital computation unit. After an input signal is provided to and processed by the phase locked loop unit, the maximum hold circuit outputs a self test output signal exhibiting the occurrence situation of jitter signal of the phase locked loop unit.

### BACKGROUND OF THE INVENTION

1. Field of the Invention

The present invention relates to a built-in-self-testing (BIST) circuit with digital output for phase locked loops-jitter testing and, more particularly, to a test circuit built in a phase locked loop circuit system for testing for jitter signals.

2. Description of Related Art

Under the trend of continual enhancement of performances of electronic products, the circuit design of integrated circuit (IC) used in electronic products becomes more and more complex. Tens of thousands of transistors or more are placed in IC devices. The test difficulty of various efficiencies of IC becomes more and more severe. Along with popularization and application of system on a chip (SOC), the IC test cost occupies a higher and higher percentage of IC sale price. Test techniques therefore become an important research issue in determination of IC performance/price.

Phase locked loops (PLL) are usually used for chip clock synthesis, bit and symbol timing recovery of serial data stream, and radio frequency carrier of the frequency division multiple access technique in communication systems. The largest problem in test of phase-locked loops is the occurrence of abnormal signal jitter situation when the input signal is a high frequency signal. At this moment, the frequency of jitter signal in the phase locked loops may be several times or even several hundreds of times of the frequency of original input signal. Therefore, it is difficult to test this high frequency jitter signal, or expensive delicate test equipments need to be used for test.

As shown in FIG. 1, a conventional jitter signal test circuit device of phase locked loops comprises a phase detector 11 electrically connected to an input signal 01, a filter 22 electrically connected to the phase detector 11, a voltage controlled oscillator (VCO) 33 electrically connected to the filter 22, and a frequency divider 44 electrically connected to the VCO 33 and the phase detector 11. The VCO 33 outputs an output signal 02. The frequency divider 44 outputs a feedback signal 03 electrically connected to the phase detector 11.

The working principle of phase locked loops is described below. The phase detector 11 compares the phases of the input signal 01 and the feedback signal 03 outputted by the frequency divider 44 and then outputs a DC voltage proportional to the phase difference of them. The filter 22 filters out undesirable frequencies and noises outputted by the phase detector 11. After the amplified DC voltage is inputted to the VCO 33, an output signal 02 with multiple frequencies is produced. After the frequency divider 44 performs frequency drop processing of some times (assuming N times) to the input signal 01, a feedback signal 03 is outputted to the phase detector 11. After phase locking finally, the frequency of the feedback signal 03 is almost the same as that of the input signal 01, and the frequency of the output signal 02 is N times that of the input signal 01.

When signal jitter situation occurs inside of the PLL, the output signal 02 will have a very high frequency after N-times amplification even though the jitter frequency range is very small. At this time, the test of jitter signal will be very severe. This situation will be worse when phase locked loops are applied to high frequency communications. Because the processing of high frequency signal is difficult, expensive high frequency test equipments need to be used for test of phase locked loops, and more test time will be wasted.

Accordingly, the conventional jitter signal test circuit device of phase locked loops has inconvenience and drawbacks in practical use. The present invention aims to solve the above problems in the prior art.

### SUMMARY OF THE INVENTION

One object of the present invention is to solve the problems of difficult processing and test of high frequency signals encountered in test of jitter signal of phase locked loops.

To solve the above object, the present invention provides a built-in-self-testing (BIST) circuit with digital output for phase locked loops-jitter testing and the method thereof, which comprises a phase locked loop unit, for generating a signal with stable and multiple frequencies; an input signal, electrically connected to the phase locked loop unit, for providing the required working frequency signal; a frequency divide unit, electrically connected to the phase locked loop unit and the input signal, for dividing the signal frequency; a signal conversion unit, electrically connected to the frequency divide unit, for performing signal conversion; a digital computation unit, electrically connected to the signal conversion unit, for computation of digital signal; a maximum hold circuit, electrically connected with the digital calculation unit, for holding output of the maximum signal; and a self test output signal, electrically connected to the maximum hold circuit, for exhibiting the occurrence situation of jitter signal of the phase locked loop unit. The phase locked loop unit outputs a feedback signal and the input signal to the frequency divide unit.

After signal frequency drop, signal conversion, digital signal computation, and signal holding in the method for operating a jitter signal circuit device having digital output and built-in-self-test phase locked loops of the present invention, high frequency signals encountered during test of jitter signal of phase locked loops can be effectively reduced, and the digital output can further enhance the convenience in subsequent applications.

The various objects and advantages of the present invention will be more readily understood from the following detailed description when read in conjunction with the appended drawing, in which:

### BRIEF DESCRIPTION OF THE DRAWINGS

FIG. 1 is a block diagram of a conventional jitter signal test circuit device of phase locked loops;

FIG. 2 is a block diagram of a built-in-self-testing (BIST) circuit with digital output for phase locked loops-jitter testing of the present invention;

FIG. 3 is a block diagram of built-in-self-test circuit units of a built-in-self-testing (BIST) circuit with digital output for phase locked loops-jitter testing of the present invention;

FIG. 4 is a block diagram of the maximum hold circuit with digital output; and

FIG. 5 is a flowchart of a method for operating a built-in-self-testing (BIST) circuit with digital output for phase locked loops-jitter testing of the present invention.

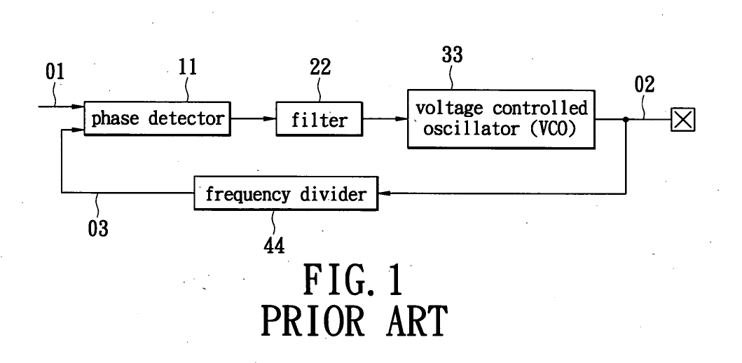

### DETAILED DESCRIPTION OF THE PREFERRED EMBODIMENTS

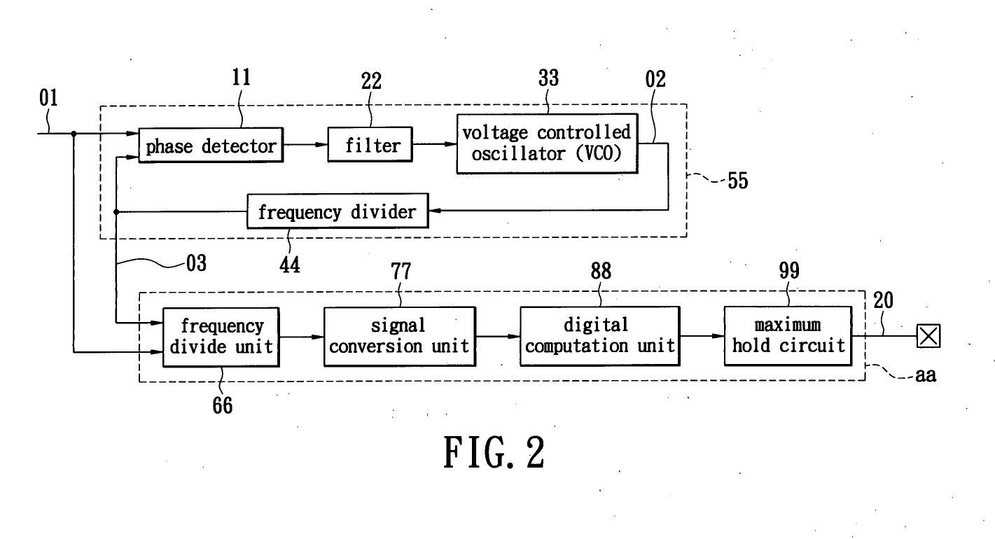

As shown in FIG. 2, a built-in-self-testing (BIST) circuit with digital output for phase locked loops-jitter testing and the method thereof of the present invention comprises a phase locked loop unit 55 for generating a signal with stable and multiple frequencies. An input signal 01, electrically connected to the phase locked loop unit 55, for providing the reference frequency signal for the phase locked loop unit 55. The input signal 01 and a feedback signal 03 produced by the phase locked loop unit 55 are electrically connected to the a frequency divide unit 66, which downs the frequencies of the input signal 01 and the feedback signal 03.

The output terminal of the frequency divide unit 66 is electrically connected with a signal conversion unit 77 used for converting a frequency signal into a voltage signal and then converting an analog signal of voltage type into a digital signal of voltage type. A digital computation unit 88 is electrically connected to output terminal of the signal conversion unit 77. The digital computation unit 88 is used for computation of digital signal. After processed by the digital computation unit 88, the signal is sent to a maximum hold circuit 99.

After the above maximum hold circuit 99 receives the output signal of the digital computation unit 88, the maximum value of the received digital signal is held and used as a self test output signal 20 for exhibiting the occurrence situation of jitter signal of the phase locked loop unit 55.

Please refer to FIG. 2 again. The above phase locked loop unit 55 comprises a phase detector 11 electrically connected to an input signal 01, a filter 22 electrically connected to the phase detector 11, a voltage controlled oscillator (VCO) 33 electrically connected to the filter 22, and a frequency divider 44 electrically connected to the VCO 33 and the phase detector 11. The VCO 33 outputs an output signal 02. The frequency divider 44 outputs a feedback signal 03, which is electrically connected to the phase detector 11. The filter 22 can be a high-pass filter, a ring filter, or a low-pass filter.

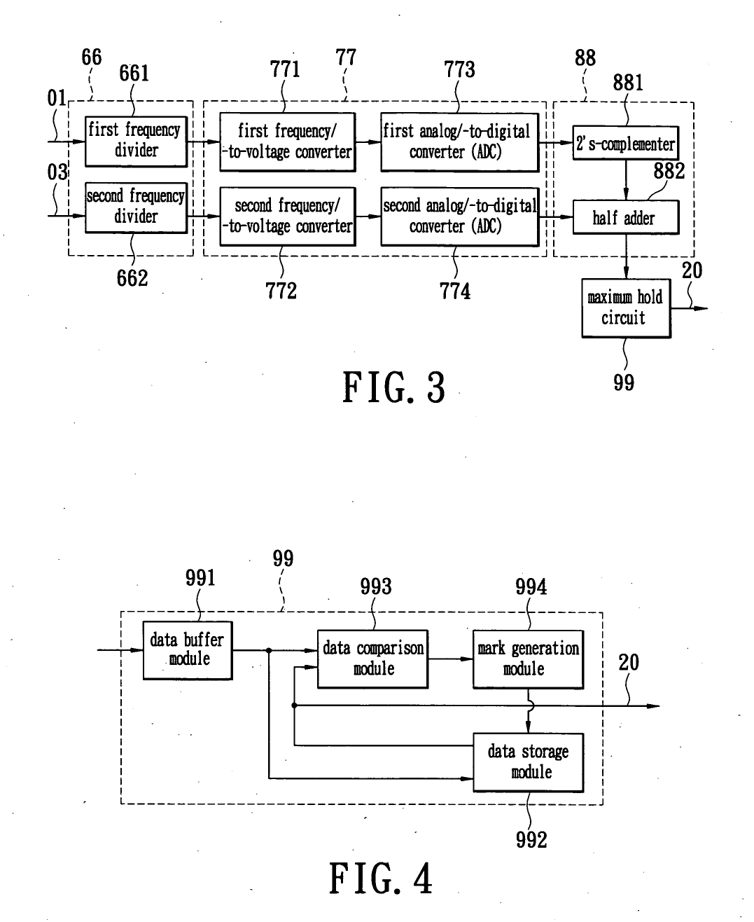

Please refer to FIG. 3 as well as FIG. 2. The frequency divide unit 66 comprises a first frequency divider 661 and a second frequency divider 662. The first frequency divider 661 receives the input signal 01. The second frequency divider 662 receives the feedback signal 03. The first and second frequency dividers 661 and 662 perform frequency down processing to the received signals, respectively. The first and second frequency dividers 661 and 662 should have the same times of frequency down function.

The above signal conversion unit 77 comprises a first frequency/-to-voltage converter 771, a second frequency/-to-voltage converter 772, a first analog/-to-digital converter (ADC) 773, and a second ADC 774. The first frequency/-to-voltage converter 771 receives the lower frequency signal outputted by the first frequency divider 661. The second frequency/-to-voltage converter 772 receives another lower frequency signal outputted by the second frequency divider 662. The first and second frequency/-to-voltage converters 771 and 772 convert the frequency signals from frequency signals into voltage signals, respectively. The first ADC 773 receives the output voltage signal of the first frequency/-to-voltage converter 771. The second ADC 774 receives the output voltage signal of the second frequency/-to-voltage converter 772. The first and second ADC 773 and 774 convert the received voltage signals from analog signals into digital signals, respectively. The first and second frequency/-to-voltage converters 771 and 772 should have the same conversion efficiency, and the first and second ADC 773 and 774 should also have the same conversion efficiency.

The above digital computation unit 88 comprises a 2's-complementer 881 and a half adder 882. After the 2's-complementer 881 receives the digital signal outputted by the first ADC 773 and performs 2's complement operation, the signal is inputted to the half adder 882. The digital signal outputted by the second ADC 774 is also sent to the half adder 882. After the half adder 882 receives the digital signals outputted by the 2's-complementer 881 and the second ADC 774, it performs a half addition and then outputs a digital signal to the maximum hold circuit 99. Finally, the maximum hold circuit 99 holds the maximum value of the received digital signal and uses it as a self-test output signal 20.

The above maximum-hold circuit 99 can be designed as shown in FIG. 4. The maximum hold circuit 99 comprises a data buffer module 991 for receiving the digital signal outputted by the half adder 882. After data buffer processing, the data buffer module 991 outputs the signal to a data storage module 992 and a data comparison module 993. After data storage processing by the data storage module 992, the signal is outputted to the data comparison module 993. The data comparison module 993 compares the magnitudes of the output signals of the data buffer module. 991 and the data storage module 992, the signal is outputted to a mark generation module 994.

If the magnitude of the output signal of the data buffer module 991 is larger than that of the output signal of the data storage module 992, the mark generation module 994 will generate a mark signal, which writes the output signal of the data buffer module 991 into the data storage module 992 at the same time to accomplish the object of holding the maximum value of the digital signal. In addition to being connected to the data comparison module 993, the output terminal of the data storage module 992 is also used as the final output signal of the maximum hold circuit 99, i.e., the self test output signal 20.

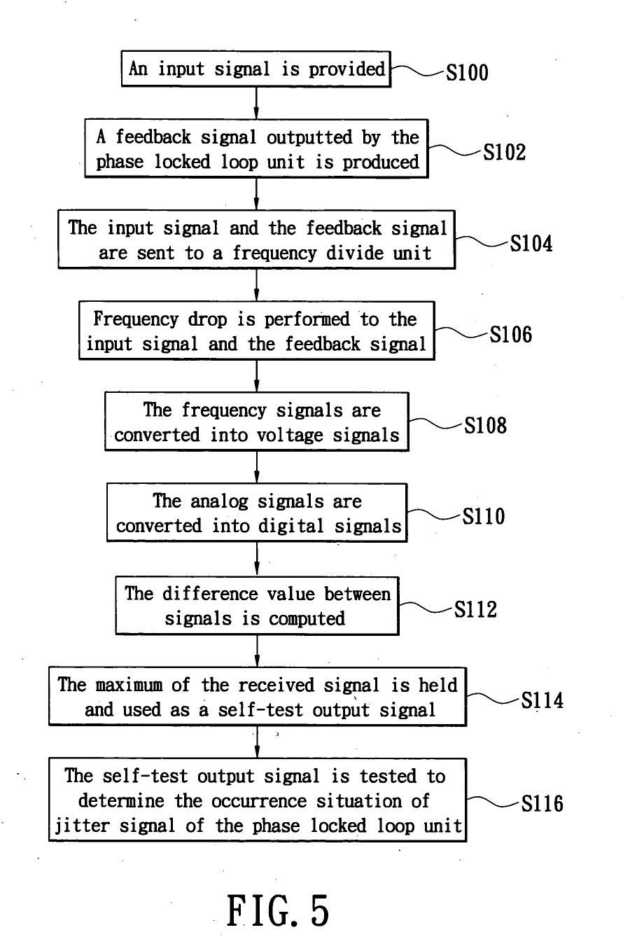

As shown in FIG. 5, a method for operating a built-in-self-testing (BIST) circuit with digital output for phase locked loops-jitter testing of the present invention comprises the following steps. First, a frequency signal is provided as an input signal and inputted to a phase locked loop unit (Step S100). After phase locking by the phase locked loop unit, a feedback signal having a frequency close to that of the input signal is produced (Step S102). Next, the input signal and the feedback signal outputted by the phase locked loop unit are inputted to a frequency divide unit (Step S104). The frequency divide unit then performs frequency down processing of the same times to the input signal and the feedback signal (Step S106). Subsequently, the input signal and the feedback signal are converted from frequency signals into voltage signals (Step S108). The voltage signals are then converted from analog to digital (Step S110). Subtraction of the digital signals is performed (Step S112). Next, the maximum value of the received digital signal is held and used as a self-test output signal (Step S114). Finally, the self-test output signal is tested to determine the occurrence situation of jitter signal of the phase locked loop unit (Step S116).

To sum up, the present invention can effectively reduce high frequency signals encountered during test of jitter signal of phase locked loops. The built-in-self-testing (BIST) circuit with digital output for phase locked loops-jitter testing of the present invention won't damage phase locked loops, and can almost exhibit the occurrence situation of actual jitter signal. Moreover, it is not necessary to change the original design of phase locked loops. Moreover, the present invention can provide a digital output, and has a better immunity to noise.

Although the present invention has been described with reference to the preferred embodiment thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A built-in-self-testing (BIST) circuit with digital output for phase locked loops-jitter testing comprising:
a phase locked loop unit, for generating a signal with stable and multiple frequencies;
an input signal, electrically connected to said phase locked loop unit, for providing the required working frequency signal;
a frequency divide unit, electrically connected to said phase locked loop unit and said input signal, for dividing signal frequency;
a signal conversion unit, electrically connected to said frequency divide unit, for performing signal conversion;
a digital computation unit, electrically connected to said signal conversion unit for computation of digital signals;
a maximum hold circuit, electrically connected with said digital computation unit, for holding output of the maximum signal; and
a self-test output signal, electrically connected to said maximum hold circuit, for exhibiting the occurrence situation of jitter signal of said phase-locked loop unit;
whereby said phase locked loop unit outputs a feedback signal and said input signal to said frequency divide unit.

2. The built-in-self-testing (BIST) circuit with digital output for phase locked loops-jitter testing as claimed in claim 1, wherein said phase locked loop unit comprises:
a phase detector, electrically connected with said input signal;
a filter, electrically connected with said phase detector, for filtering out undesirable frequencies and noises;
a voltage controlled oscillator, electrically connected with said filter, for generating a multi-frequency signal having a frequency some times of said input signal; and
a frequency divider, electrically connected with said voltage controlled oscillator, said phase detector and said frequency divide unit, for splitting said multi-frequency signal generated by said voltage controlled oscillator and finally outputting a feedback signal to said phase detector and said frequency divide unit.

3. The phase locked loop unit of the built-in-self-testing (BIST) circuit with digital output for phase locked loops-jitter testing as claimed in claim 2, wherein said filter is a high-pass filter.

4. The phase locked loop unit of the built-in-self-testing (BIST) circuit with digital output for phase locked loops-jitter testing as claimed in claim 2, wherein said filter is a ring filter.

5. The phase locked loop unit of the built-in-self-testing (BIST) circuit with digital output for phase locked loops-jitter testing as claimed in claim 2, wherein said filter is a low-pass filter.

6. The built-in-self-testing (BIST) circuit with digital output for phase locked loops-jitter testing as claimed in claim 2, wherein said frequency divide unit comprises:
a first frequency divider, electrically connected with said input signal, for dividing the frequency of said input signal; and
a second frequency divider, electrically connected with said feedback signal outputted by said frequency divider of said phase locked loop unit, for dividing the frequency of said feedback signal.

7. The frequency divide unit of the built-in-self-testing (BIST) circuit with digital output for phase locked loops-jitter testing as claimed in claim 6, wherein said first and second frequency dividers have the same times of frequency dividing.

8. The built-in-self-testing (BIST) circuit with digital output for phase locked loops-jitter testing as claimed in claim 6, wherein said signal conversion unit comprises:
a first frequency/-to-voltage converter, electrically connected with said first frequency divider, for converting a frequency signal into a voltage signal;
a second frequency/-to-voltage converter, electrically connected with said second frequency divider, for converting a frequency signal into a voltage signal;
a first analog/-to-digital converter, electrically connected with said first frequency/-to-voltage converter, for converting an analog signal into a digital signal; and
a second analog/-to-digital converter, electrically connected with said second frequency/-to-voltage converter, for converting an analog signal into a digital signal.

9. The signal conversion unit of the built-in-self-testing (BIST) circuit with digital output for phase locked loops-jitter testing as claimed in claim 8, wherein said first and second frequency/voltage converter have the same conversion efficiency.

10. The signal conversion unit of the built-in-self-testing (BIST) circuit with digital output for phase locked loops-jitter testing as claimed in claim 8, wherein said first and second analog/-to-digital converters have the same conversion efficiency.

11. The signal conversion unit of the built-in-self-testing (BIST) circuit with digital output for phase locked loops-jitter testing as claimed in claim 1, wherein said digital computation unit comprises:
a 2's-complementer, electrically connected with said first analog/-to-digital converter, for performing 2's complement operation of digital signal; and
a half adder, electrically connected with said second analog/-to-digital converter and said 2's-complementer, for performing the operation of half addition of two digital signals.

12. The signal conversion unit of the built-in-self-testing (BIST) circuit with digital output for phase locked loops-jitter testing as claimed in claim 1, wherein said maximum hold circuit, electrically connected with said half adder, for holding the maximum value of the received digital signal.

13. A method for operating a built-in-self-testing (BIST) circuit with digital output for phase locked loops-jitter testing comprising the steps of:
providing an input signal;
generating a feedback signal outputted by said phase locked loop unit;
sending said input signal and said feedback signal to a frequency divide unit;
performing frequency down processing to said input signal and said feedback signal;
converting the frequency signals into voltage signals;
converting the analog signals into digital signals;
computing the difference value between the digital signals;
holding the maximum value of the received signal and using it as a self test output signal; and
testing said self test output signal to determine the occurrence situation of jitter signal of said phase locked loop unit.

14. The method for operating a built-in-self-testing (BIST) circuit with digital output for phase locked loops-jitter testing as claimed in claim 13, wherein said input signal provided in said step of providing an input signal is a frequency signal.

15. The method for operating a built-in-self-testing (BIST) circuit with digital output for phase locked loops-jitter testing as claimed in claim 13, wherein said input signal and said feedback signal in said step of performing frequency drop processing to said input signal and said feedback signal have the same times of frequency dividing.

16. The method for operating a built-in-self-testing (BIST) circuit with digital output for phase locked loops-jitter testing as claimed in claim 13, wherein subtraction of digital signals is performed in said step of computing the difference value between the digital signals.

17. The method for operating a built-in-self-testing (BIST) circuit with digital output for phase locked loops-jitter testing as claimed in claim 13, wherein the maximum value of the received digital signal is held in said step of holding the maximum value of the received signal.
